(19) United States
(12) Patent Application Publication
(10) Pub. No.: US 2015/0263694 A1
(43) Pub. Date: Sep. 17, 2015

(54) PCB FOR REDUCING ELECTROMAGNETIC INTERFERENCE OF ELECTRIC VEHICLE

(71) Applicant: LSIS CO., LTD., Anyang-si (KR)

(72) Inventor: Jong In SUN, Incheon-si (KR)

(73) Assignee: LSIS CO., LTD., Anyang-si (KR)

(21) Appl. No.: 14/637,040

(22) Filed: Mar. 3, 2015

(30) Foreign Application Priority Data
Mar. 17, 2014 (KR) 10-2014-0030950

(51) Int. Cl. H03H 1/00; H05K 1/18; B60L 11/18

(52) U.S. Cl. CPC H03H 1/00; B60L 11/1816; H05K 1/18; H03H 2001/0014; H05K 2201/0776; H05K 2201/1003

(57) ABSTRACT

A printed circuit board (PCB) for reducing EMI of an electric vehicle is provided. The PCB includes an electromagnetic interference (EMI) filter connected to a battery power supply and filtering EMI noise, a plurality of chassis ground (GND) terminals, a chassis GND pattern formed to ground a power GND terminal to the plurality of chassis GND terminals, a coupling prevention capacitor installed between the power GND terminal and the plurality of chassis GND terminals to prevent noise coupling between the power GND terminal and the chassis GND terminals, and a merge resistor installed between the power GND terminal and the plurality of chassis GND terminals to merge noise occurring when charging the battery power supply to the plurality of chassis GND terminals.

### CROSS-REFERENCE TO RELATED APPLICATIONS

Pursuant to 35 U.S.C. §119(a), this application claims the benefit of earlier filing date and right of priority to Korean Patent Application No. 10-2014-0030950, filed on Mar. 17, 2014, the contents of which are hereby incorporated by reference herein in its entirety.

### BACKGROUND

The present disclosure relates to a printed circuit board (PCB) for reducing electromagnetic interference (EMI) in high voltage electronic devices of an electric vehicle, and particularly, to a PCB for reducing EMI of an electric vehicle for reducing EMI noise in a high voltage electronic device PCB level by connecting a ground with an electric flow to a chassis ground without an electric flow, pattern-forming a chassis ground on a PCB artwork on an outer perimeter surface, and connecting a Y-capacitor at a front stage of an EMI filter to the chassis ground to improve an EMI filter effect.

Recently, environmentally friendly vehicles attract interests due to environmental problems, and expectations are increased in mass production and popularization of electric vehicles among the environmentally friendly vehicles. In particular, interests are increased in a noise reducing technology in terms of the EMI according to high electric use characteristics of electronic devices of the electric vehicles. Furthermore, noise level specification for EMI is enforced to electronic device manufacturers in domestic and foreign original equipment manufacturing (OEM) fields of the electronic vehicles, and international organizations enforce criteria for reducing the EMI noise of the electronic devices. Accordingly, electronic device manufacturers meet a more and more severe environment in developing electronic devices.

The core of driving an electric vehicle lies in a battery component. In particular, there are various EMI noise components inside the electric vehicle, such as a charging noise occurring in charging a battery, or a switching noise of a charger itself, and interests are increased in a technology for reducing the various EMI noises.

The EMI is a noise source of an unwanted wideband noise and means that the noise causes interference and hindrance to an electromagnetic wave.

A power source noise is largely divided into a common mode noise and a normal mode noise. First, the common mode noise indicates that noises in plus and minus ends of a power source flow in the same direction and is called a CM noise.

The normal mode noise indicates that noises in the plus and minus ends of the power source flow in different directions and is called a DM noise. Accordingly, a filter reducing the CM noise is called a CM filter, and a filter reducing the DM noise is called a DM filter.

An EMI filter includes a CM filter and a DM filter.

FIG. 1 illustrates a typical EMI filter in a high voltage electronic device of an electric vehicle.

Referring to FIG. 1, the typical EMI filter has a structure having a DM filter 2 connected to a battery 1, and a CM filter 3 connected to the DM filter 2 with a Y capacitor 3 intervened in-between.

The DM filter 2 includes a Tr type capacitor, and the CM filter 4 includes an inductor and a capacitor. The Y capacitor 3 draws out a noise component which passes through the DM filter 2 to a chassis ground (i.e., an earth GND).

The DM filter 2 first absorbs and reduces a noise component induced in a low voltage battery 1, which accordingly increases capacity of a capacitor and an inductance value of an inductor of the DM filter 2.

Actually, it is confirmed that a noise filtering effect in the DM filter 2 is small during measuring a noise level in an EMI test laboratory. Furthermore, since the noise induced in the low voltage battery 1 is induced to the DM filter 2 in a mixed type of the CM noise and the DM noise, in case of analysis in terms of the DM filter 2, the CM noise passes without being filtered out and is drawn out to the chassis GND (the earth) through the Y capacitor 3 without a change.

In particular, since an impedance component is varied according to characteristics of each electronic device due to connector impedance in the high voltage electronic device and a harness connected to the connector, it is difficult to determine which noise of the CM and DM noises causes a problem.

In addition, only the DM noise is filtered by a first capacitor C1, first inductor L1, and second capacitor C2 of the DM filter 2, and the DM and CM noises are filtered through the Y capacitors Cy1 and Cy2.

That is, since the CM noise is filtered after passing through the DM filter 2, there is no noise reduction effect in case of products having much CM noise.

FIG. 2 is a view for illustrating an effect of a noise generated when a typical EMI filter is connected to a switched-mode power supply (SMPS).

Referring to FIG. 2, the EMI filter (DM filter) 2 is installed in the battery 1 and the SMPS 5 is connected to the EMI filter (DM filter) 2.

Typically, although this kind of power supply circuit is configured under premise that a noise component is reduced by the EMI filter (DM filter) 2, a noise actually remains even after passing the EMI filter (DM filter) 2. The noise passing through the EMI filter (DM filter) 2 may also become increased from a small noise state by the SMPS 5. Accordingly, the noise remaining after passing through the EMI filter (DM filter) 2 is required to be reduced before entering the SMPS 5.

In order to reduce the noise induced in the low voltage battery, the EMI noise of the electronic device directly connected to the low voltage battery stage is required to be reduced and to this end, the noise is primarily required to be reduced through the EMI filter.

Although a noise reducing technology through the EMI filter is extended from an industrial electronic device to an automotive electronic device, a noise reduction effect is negligible with a typical EMI filter in the automotive electronic device having high noise criteria.

In terms of characteristics of an electric vehicle, a low noise battery is weaker to a noise than a battery of an internal combustion engine according to electric driving and load characteristics.

Side effect characteristics, such as life-shortening of a battery and fuel-efficiency reduction, become high, as a noise component becomes great in the low voltage battery. Accordingly, a noise induced in the low voltage battery is necessary to be reduced. In addition, OEM companies of the domestic and foreign electric vehicle manufacturers also acutely feel this necessity.

As described above, it is typically recognized that EMI reducing technology is a measure of reducing an EMI noise level by using an EMI filter. Importance of an EMI filter is not surely excluded. An EMI filter, namely, a capacitor and an inductor, or a Tr type filter through a capacitor is an important design factor for reducing EMI noise.

A circuit behind the EMI filter mostly includes a power supply unit. The circuit is configured so due to determination that a noise component is reduced by the EMI filter, but in practical, it is natural that noise still exists after passing the EMI filter. Even though noise passing through the EMI filter 2 may also become increased from a small noise state by the SMPS 5, the noise passing through the EMI filter exists. Measures for reducing noise occurred in this way are necessary.

The reason that EMI reducing measures through an EMI filter are less effective is that there are no measures for reducing various EMI noises occurred at PCB level. In other words, the high voltage electronic device receives power through various connectors and noise is increased in a process of CAN communication with an upper layer controller of a vehicle or by EMI noise coupling in a power conversion process. In addition, the important factor is that an EMI noise at PCB level is the most problematic due to co-existence of high voltage ground and low voltage ground at PCB level and impedance increases at connectors with a PCB.

After power application, an EMI noise forming an electromagnetic field with pattern and connector impedance occurs at PCB level. A measure is necessary for passing noise occurring at this PCB level to a chassis ground (earth).

However, measures are not implemented at PCB level besides an EMI filter on an artwork. In most cases, a PCB artwork is performed without EMI reducing measures at PCB level besides an EMI filter at an electrical connection portion.

### SUMMARY

Embodiments provide a printed circuit board (PCB) for EMI reduction in an electric vehicle for EMI noise reduction at high voltage electronic device PCB level by connecting a ground with an electrical flow to a chassis ground without an electrical flow, pattern-forming a chassis ground on a PCB artwork on an outer perimeter surface of the PCB, and connecting a Y-capacitor to the ground at a front stage of an EMI filter for improving an EMI filter effect.

The objectives of the present invention are not limited to the above-described. The objectives not mentioned in the above should be clearly understood by those skilled in the art from description below.

In one embodiment, a printed circuit board (PCB) for reducing EMI of an electric vehicle, includes: an electromagnetic interference (EMI) filter connected to a battery power supply and filtering EMI noise; a plurality of chassis ground (GND) terminals; a chassis GND pattern formed to ground a power GND terminal to the plurality of chassis GND terminals; a coupling prevention capacitor installed between the power GND terminal and the plurality of chassis GND terminals to prevent noise coupling between the power GND terminal and the chassis GND terminals; and a merge resistor installed between the power GND terminal and the plurality of chassis GND terminals to merge noise occurring when charging the battery power supply to the plurality of chassis GND terminals.

The chassis GND pattern may have a width for electrically connecting the plurality of chassis GND terminals to each other and is formed around an outer perimeter surface of the PCB.

The PCB may further include a Y capacitor installed between the battery power supply and the EMI filter to reduce noise reduction.

The PCB according to claim 1, wherein the power GND terminal is electrically connected to a point of the chassis GND pattern, which has a minimum distance to the chassis GND pattern.

The merge resistor is installed in proximity of a power connector into which power from the battery power supply is input.

The merge resistor may be a 0Ω resistor.

The details of one or more embodiments are set forth in the accompanying drawings and the description below. Other features will be apparent from the description and drawings, and from the claims.

### BRIEF DESCRIPTION OF THE DRAWINGS

FIG. 1 illustrates a typical EMI filter.

FIG. 2 is a view for illustrating an effect of a noise generated when a typical EMI filter is connected to a switched-mode power supply (SMPS).

FIG. 3 is a circuit diagram of a PCB for EMI reduction of an electric vehicle according to an embodiment.

FIG. 4 illustrates a PCB for EMI reduction of an electric vehicle according to an embodiment.

FIG. 5 is a graph showing a noise reduction effect of a PCB for EMI reduction in electric vehicle according to an embodiment.

FIG. 6 is a graph showing a measurement result of conducted emission (CE) measured in a PCB including a typical EMI filter illustrated in FIG. 1.

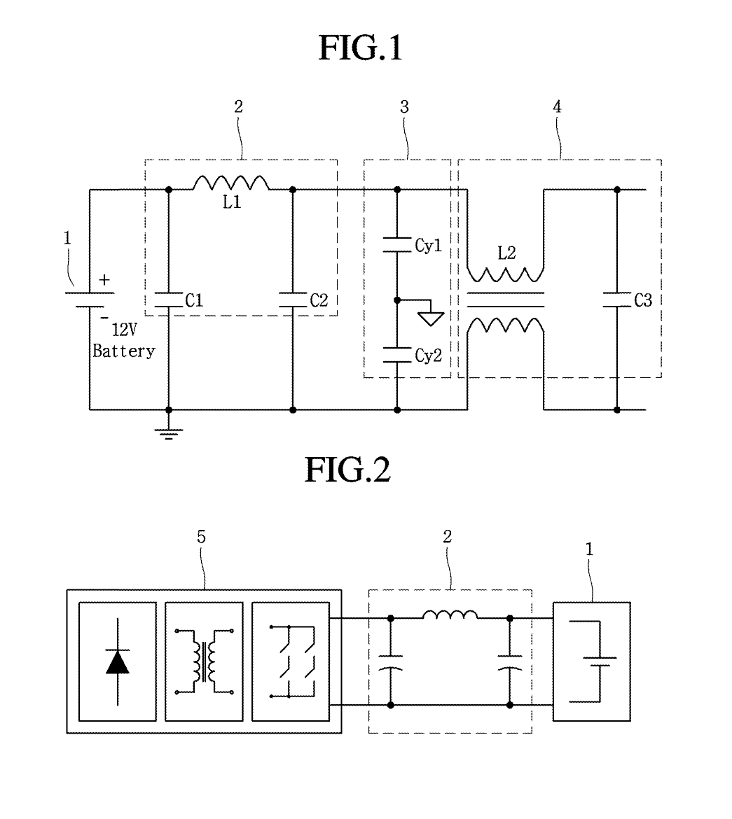

### DETAILED DESCRIPTION OF THE EMBODIMENTS

Reference will now be made in detail to the embodiments of the present disclosure, examples of which are illustrated in the accompanying drawings.

The invention may, however, be embodied in many different forms and should not be construed as being limited to the embodiments set forth herein; rather, that alternate embodiments included in other retrogressive inventions or falling within the spirit and scope of the present disclosure can easily be derived through adding, altering, and changing, and will fully convey the concept of the invention to those skilled in the art.

The terms used in this specification were selected to include current, widely-used general terms. In certain cases, a term may be one that was arbitrarily established by the applicant. In such cases, the meaning of the term will be defined in the relevant portion of the detailed description. As such, the terms used in the specification are not to be defined simply by the name of the terms but are to be defined based on the meanings of the terms as well as the overall description of the present disclosure.

Throughout this specification, when an element is referred to as “including” a component, it does not preclude another component but may further include the other component unless the context clearly indicates otherwise.

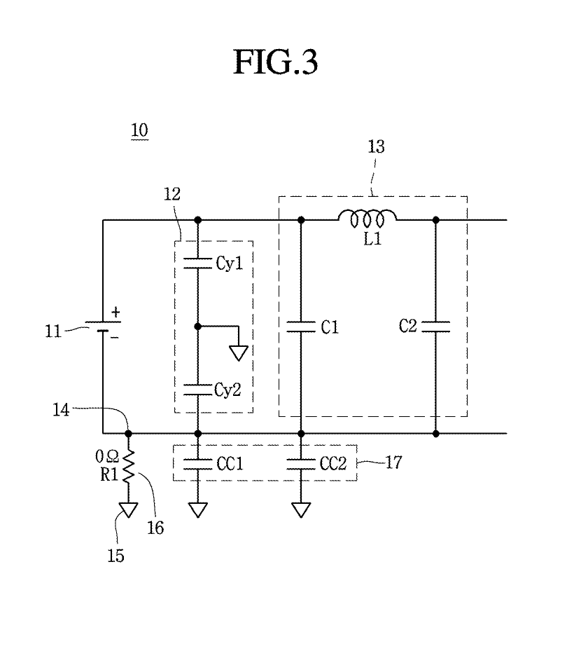

FIG. 3 is a circuit diagram of a printed circuit board (PCB) for EMI reduction of an electric vehicle according to an embodiment.

Referring FIG. 3, a PCB 10 for reducing EMI of an electric vehicle according to an embodiment includes a Y capacitor 12 between a cathode terminal and an anode terminal of a battery 11. An EMI filter 13 is connected to both terminals of the Y capacitor 12. Here, the EMI filter 13 may be implemented with a DM filter including π type capacitors C1 and C2. However, the EMI filter 13 is not limited hereto and may be implemented with a CM filter including an inductor and a capacitor.

The Y capacitor 12 may be installed between the cathode terminal and a power ground terminal 14 of a battery power supply 11 to allow noise component passing through the EMI filter 13 to output to the power GND terminal 14.

Furthermore, a merge resistor 16 and a coupling prevention capacitor 17 are installed between the power GND terminal 14 with an electric flow and a chassis GND terminal 15 without an electrical flow.

At this point, the merge resistor 16 may be installed in proximity of a power connecter into which power from the battery power supply 11 is input.

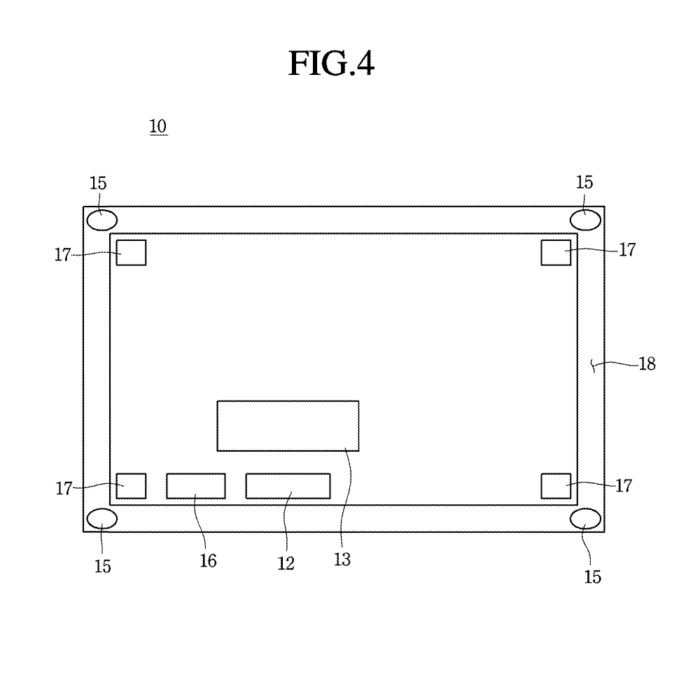

FIG. 4 view for explaining a PCB for EMI reduction of an electric vehicle according to an embodiment.

Referring to FIG. 4, a PCB 10 for reducing EMI of an electric vehicle may include a Y capacitor 12, an EMI filter 13, chassis GND terminals 15, a merge resistor 16, a coupling prevention capacitor 17, and a chassis GND pattern 18.

The chassis GND terminal 15 may be formed in plurality on the PCB 10. For example, the chassis GND terminals 15 may be respectively installed on four corners of the PCB 10. However, the present disclosure is not limited hereto and positions and the number thereof may be modified according to a designer's need.

The chassis GND pattern 18 may be formed around the perimeter of the PCB 10 to include the chassis GND terminals 15. The chassis GND pattern 18 may be formed to have a certain width. The width may be determined according to a designer's need. The chassis ground pattern 18 may be formed of a conductive material for connecting the power GND terminal 14 with an electric flow and the chassis GND terminals 15 without an electric flow.

The chassis GND pattern 18 may reduce an EMI noise by connecting to the chassis GND at a point of high impedance, not by individually flowing to the chassis GND terminals 15 the EMI noise including magnetic field noise and clock frequency noise at a power pattern, which occur at PCB level.

In other words, the power GND terminal 14 including the EMI noise occurring through a power line is not allowed to be irregularly output to each of the chassis GND terminals 15, and the GND terminals 15 and the power GND terminal 14 are consistently connected at the point of high impedance.

In this way, the chassis GND pattern 18 is formed to surround the chassis GND terminals 15 around the perimeter region of the PCB for consistently and rapidly drawing the power GND terminal having noises occurring at PCB level out to the chassis GND terminals 15.

The Y capacitor 12 is installed at a front stage of the EMI filter 13 for improving the EMI filter effect and may be connected to the chassis GND terminals 15 through the chassis GND pattern 18.

The chassis GND terminals 15 have high impedance at bolt joint parts where the PCB 10 is connected to an external housing of electronic devices. Through the chassis GND terminal 15, the EMI noise may be abandoned to the power GND terminal 14, or on the contrary a noise component at the power GND terminal 14 may be coupled to the chassis GND terminals 15.

The merge resistor 16 is installed to merge the chassis GND terminals 15 and the power GND terminal 14 through 0Ω resistor to reduce the noise.

The coupling prevention capacitor 17 is installed to cut off the EMI noise from being abandoned to the power GND terminal 14 through the chassis GND terminals 15 or on the contrary the noise component at the power GND terminal 14 from being coupled to the chassis GND terminals 15.

Accordingly, the coupling prevention capacitor 17 may be installed between the chassis GND terminals 15 and the power GND terminal 14 to cut off and control the irregularly abandoned EMI noise component.

The Y capacitor 12 is included in the front stage of the EMI filter 13. The Y-capacitor 12 may reduce the EMI noise component with the chassis GND terminal 15.

The EMI filter 13 may reduce a noise input through a power line, namely, a CM noise and DM noise. However, the noise component still exists despite of passing through the EMI filter 13. Accordingly, by preparing the Y capacitor 12 at the front stage of the EMI filter 13, the effect of the EMI filter 13 may be maximized, since the EMI noise to the chassis GND terminal 15 may be primarily reduced.

Noise reduction may be effective in an AM frequency band by installing the Y capacitor 12 in proximity of a power connector into which power from the battery power supply 11 is input. The capacity of the Y-capacitor 12 may be varied according to electric specification of each electronic device.

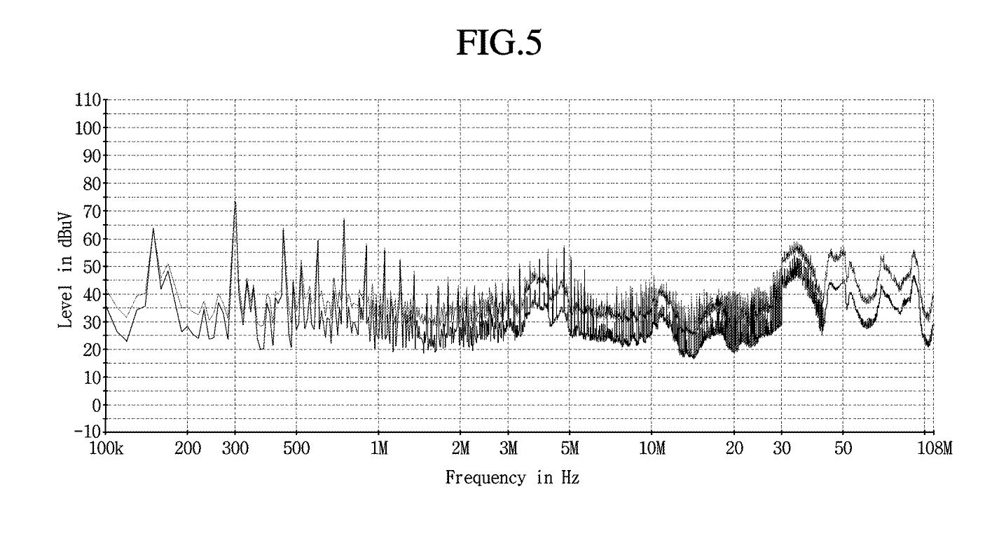

Referring to FIG. 5, from a conducted emission (CE) measurement result measured by a low voltage stage EMI filter 100 of an electric vehicle according to an embodiment, the noise level reduction effect may be confirmed across a frequency band of 150 kHz to 108 MHz.

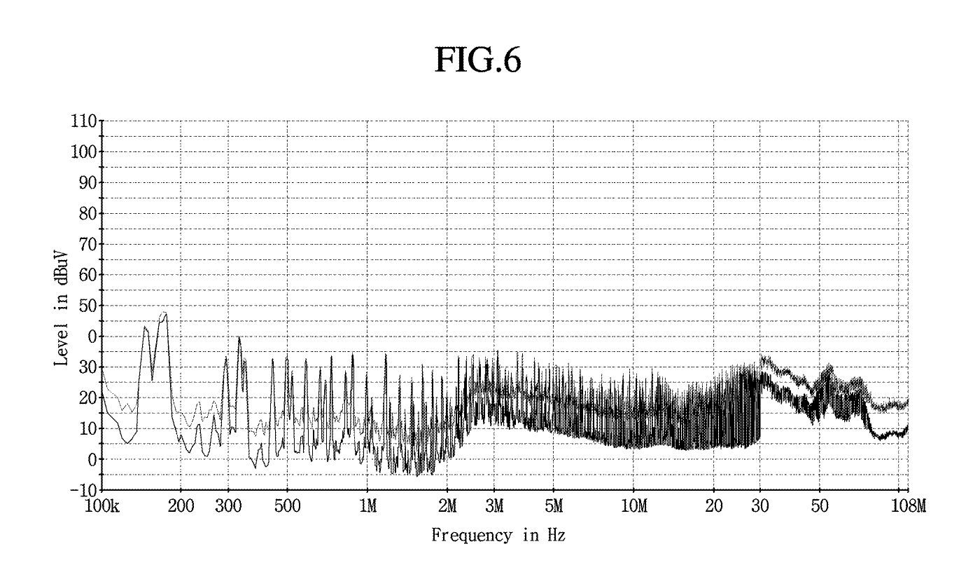

On the contrary, referring to FIG. 6, in the typical case, it may be confirmed that a noise between 150 kHz to 108 MHz sporadically occur during CE measurement. It may be also confirmed that a peak noise distribution occurs in AM and FM bands.

According to embodiments, an EMI noise reduction effect at high voltage electronic device PCB level can be provided by connecting a ground with an electrical flow to a chassis ground without an electrical flow, pattern-forming a chassis ground on a PCB artwork on an outer perimeter surface of a PCB, and connecting a Y-capacitor to the ground at a front stage of an EMI filter for improving an EMI filter effect.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A printed circuit board (PCB) for reducing EMI of an electric vehicle, the PCB comprising:
an electromagnetic interference (EMI) filter connected to a battery power supply and filtering EMI noise;
a plurality of chassis ground (GND) terminals;
a chassis GND pattern formed to ground a power GND terminal to the plurality of chassis GND terminals;
a coupling prevention capacitor installed between the power GND terminal and the plurality of chassis GND terminals to prevent noise coupling between the power GND terminal and the chassis GND terminals; and
a merge resistor installed between the power GND terminal and the plurality of chassis GND terminals to merge noise occurring when charging the battery power supply, to the plurality of chassis GND terminals.

2. The printed circuit board (PCB) according to claim 1, wherein the chassis GND pattern has a width for electrically connecting the plurality of chassis GND terminals to each other and is formed around an outer perimeter surface of the PCB.

3. The printed circuit board (PCB) according to claim 1, further comprising a Y capacitor installed between the battery power supply and the EMI filter to reduce noise reduction.

4. The printed circuit board (PCB) according to claim 3, wherein the Y capacitor is installed at a front stage of the EMI filter and connected to any one of the plurality of chassis GND terminals through the chassis GND pattern.

5. The printed circuit board (PCB) according to claim 1, wherein the power GND terminal is electrically connected to a point of the chassis GND pattern, which has a minimum distance to the chassis GND pattern.

6. The printed circuit board (PCB) according to claim 1, wherein the merge resistor is installed in proximity of a power connector into which power from the battery power supply is input.

7. The printed circuit board (PCB) according to claim 1, wherein the merge resistor is a 0Ω resistor.

8. The printed circuit board (PCB) according to claim 1, wherein the EMI filter comprises a DM filter comprising a plurality of capacitors configured in a Tr type.

9. The printed circuit board (PCB) according to claim 1, wherein the EMI filter comprises a CM filter comprising an inductor and a capacitor.

10. The printed circuit board (PCB) according to claim 1, wherein the plurality of chassis GND terminals are respectively located on corners of the PCB.
